(19) United States
(12) Patent Application Publication
(10) Pub. No.: US 2023/0003591 A1
(43) Pub. Date: Jan. 5, 2023

(54) FORCE SENSOR MODULE

(71) Applicants: SONY GROUP CORPORATION, Tokyo (JP); SONY SEMICONDUCTOR SOLUTIONS CORPORATION, Kanagawa (JP)

(72) Inventors: Tomoko KATSUHARA, Tokyo (JP); Kei TSUKAMOTO, Tokyo (JP); Hiizu OHTORII, Kanagawa (JP)

(21) Appl. No.: 17/781,491

(22) PCT Filed: Nov. 19, 2020
(86) PCT No.: PCT/JP2020/043140

§ 371 Date: Jun. 1, 2022

(30) Foreign Application Priority Data
Dec. 6, 2019 (JP) 2019-220840

(51) Int. Cl. G01L 1/20; G01L 5/22

(52) U.S. Cl. CPC G01L 1/205; G01L 5/226

(57) ABSTRACT

A force sensor module includes multiple force sensors disposed in series. The force sensors each include multiple sensor sections, a support substrate, and an organic member. The multiple sensor sections have respective force detection directions different from each other. The support substrate is separately provided for each of the force sensors and supports the multiple sensor sections. The organic member is provided in common to the force sensors. The organic member fixes the multiple force sensors in series and has a groove at a location corresponding to a gap between two support substrates adjacent to each other. The organic member is flexible.

### TECHNICAL FIELD

The present disclosure relates to a force sensor module.

### BACKGROUND ART

In order to control handling of an object by a robot, many sensors are used in the robot. Sensors usable in robots are disclosed, for example, in PTLs 1 and 2 below.

### CITATION LIST

### Patent Literature

PTL 1: US Unexamined Patent Application Publication No. 2016/0167949

PTL 2: Japanese Unexamined Patent Application Publication No. 2015-197357

### SUMMARY OF THE INVENTION

Incidentally, if it becomes possible to dispose a large number of sensors at a high density, it becomes possible to obtain various pieces of information difficult to obtain from a single sensor. In particular, in the field of robots, if it becomes possible to dispose a large number of sensors at a tip portion of a robot hand at a high density, it also becomes possible to control the robot hand more precisely. It is therefore desirable to provide a force sensor module that is able to be disposed at a high density and with a high resolution.

A force sensor module according to one embodiment of the present disclosure includes multiple force sensors disposed in series. The force sensors each include multiple sensor sections, a support substrate, and an organic member. The multiple sensor sections have respective force detection directions different from each other. The support substrate is separately provided for each of the force sensors and supports the multiple sensor sections. The organic member is provided in common to the force sensors. The organic member fixes the multiple force sensors in series and has a groove at a location corresponding to a gap between two support substrates adjacent to each other. The organic member is flexible.

In the force sensor module according to the embodiment of the present disclosure, the multiple force sensors are disposed in series by the flexible organic member. Accordingly, for example, it is possible to dispose the multiple force sensors at a high density independently of a shape of an installation target. In addition, in the present disclosure, the groove is formed in the organic member at a location corresponding to the gap between two support substrates adjacent to each other. Accordingly, when a force is inputted to the organic member from an outside, the force from the outside is inputted to the force sensor corresponding to an input position, and propagation of the force from the outside to a force sensor at a position away from the input position is suppressed. That is, the organic member has both a function of supporting the multiple force sensors in series and a function of selectively inputting the force from the outside to the force sensor corresponding to the input position. Therefore, in the present disclosure, it is possible to achieve high-density disposing of the multiple force sensors and high-resolution detection by the multiple force sensors.

### BRIEF DESCRIPTION OF DRAWINGS

FIG. 1 is a diagram illustrating an example of a plan configuration of a force sensor module according to a first embodiment of the present disclosure.

FIG. 2 is a diagram illustrating an example of a cross-sectional configuration of the force sensor module in FIG. 1.

FIG. 3 is a diagram illustrating an example of a plan configuration of the force sensor module in FIG. 2.

FIG. 4 is a diagram illustrating an example of the plan configuration of the force sensor module in FIG. 2.

FIG. 5 is a diagram illustrating a modification of the cross-sectional configuration of the force sensor module in FIG. 1.

FIG. 6 is a diagram illustrating a modification of the plan configuration of the force sensor module in FIG. 2.

FIG. 7 is a diagram illustrating a modification of the plan configuration of the force sensor module in FIG. 1.

FIG. 8 is a diagram illustrating an example of a plan configuration of a force sensor module according to a second embodiment of the present disclosure.

FIG. 9 is a diagram illustrating an example of a cross-sectional configuration of the force sensor module in FIG. 8.

FIG. 10 is a diagram illustrating an example of a plan configuration of the force sensor module in FIG. 9.

FIG. 11 is a diagram illustrating an example of the plan configuration of the force sensor module in FIG. 9.

FIG. 12 is a diagram illustrating a modification of the cross-sectional configuration of the force sensor module in FIG. 8.

FIG. 13 is a diagram illustrating a modification of the plan configuration of the force sensor module in FIG. 8.

### MODES FOR CARRYING OUT THE INVENTION

Some embodiments of the present disclosure are described below in detail with reference to the drawings. The following description is a specific example of the present disclosure, and the present disclosure is not limited to the following embodiments. In addition, the present disclosure is not limited to arrangements, dimensions, dimension ratios, etc. of respective components illustrated in each drawing. It is to be noted that the description is given in the following order.

1. First Embodiment (MEMS force sensor module)
An example in which each force sensor includes MEMS

2. Modifications of First Embodiment
Modification 1-1: An example in which multiple MEMS sections are provided on a single chip
Modification 1-2: An example in which a six-axis force sensor includes multiple MEMS sections
Modification 1-3: An example in which multiple force sensors are disposed in a serpentine manner

3. Second Embodiment (diaphragm force sensor module)
An example in which each force sensor includes a diaphragm

4. Modifications of Second Embodiment
Modification 2-1: An example in which a circuit board is mounted on a bottom surface of a diaphragm substrate
Modification 2-2: An example in which multiple force sensors are disposed in a serpentine manner

### 1. First Embodiment

### [Configuration]

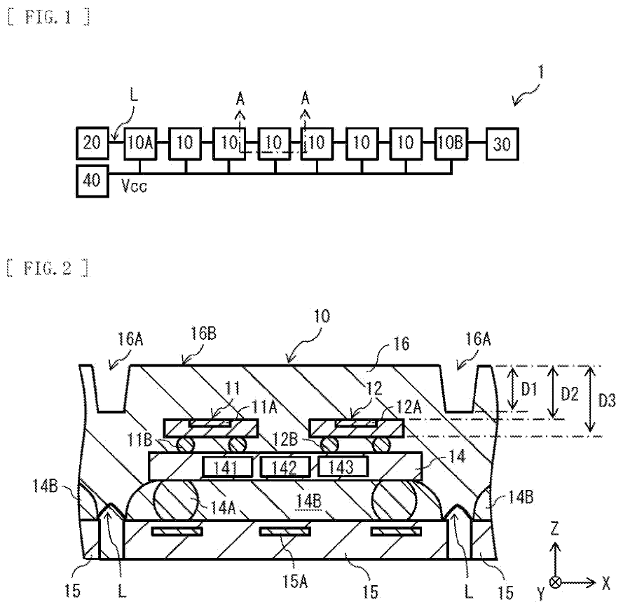

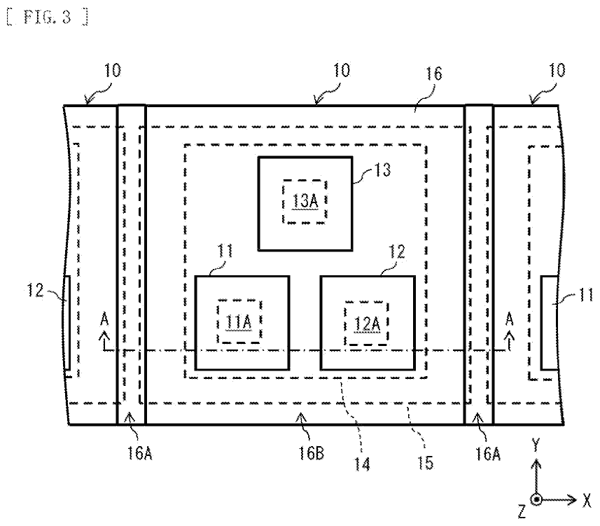

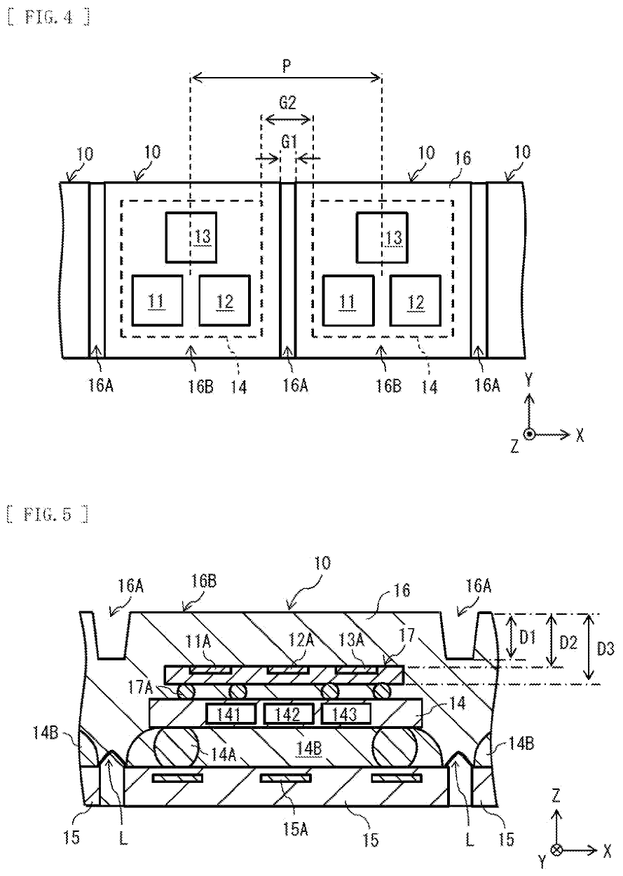

A description is given of a configuration of a MEMS force sensor module 1 according to a first embodiment of the present disclosure. FIG. 1 illustrates an example of a plan configuration of the MEMS force sensor module 1 according to the present embodiment. FIG. 2 illustrates an example of a cross-sectional configuration of the MEMS force sensor module 1 in FIG. 1 taken along a line A-A. FIGS. 3 and 4 each illustrate a portion of the example of the plan configuration of the MEMS force sensor module 1 in FIG. 2 in an enlarged manner.

The MEMS force sensor module 1 includes multiple MEMS three-axis force sensors 10 coupled in series via a coupling line L. For example, the coupling line L basically includes a clock pair differential line and a data pair differential line, and also includes several kinds of other control lines. The MEMS force sensor module 1 corresponds to a specific example of a “force sensor module” of the present disclosure. The MEMS three-axis force sensor 10 corresponds to a specific example of a “force sensor” of the present disclosure. The coupling line L corresponds to a specific example of a “coupling line” of the present disclosure.

The MEMS three-axis force sensor 10 includes sensor substrates 11, 12, and 13, a circuit board 14, a wiring substrate 15, and an organic member 16. The circuit board 14 is provided separately for each MEMS three-axis force sensor 10. The wiring substrate 15 is also provided separately for each MEMS three-axis force sensor 10. The sensor substrates 11, 12, and 13 each correspond to a specific example of a “sensor substrate” of the present disclosure. The circuit board 14 corresponds to a specific example of a “support substrate” of the present disclosure. The wiring substrate 15 corresponds to a specific example of a “wiring substrate” of the present disclosure. The organic member 16 corresponds to a specific example of an “organic member” of the present disclosure.

Each of the sensor substrates 11, 12, and 13 and the circuit board 14 are stacked on each other. The sensor substrates 11, 12, and 13 are disposed at positions opposing an upper surface of the circuit board 14. The wiring substrate 15 is disposed at a position opposing a lower surface of the circuit board 14. The organic member 16 is provided at a position opposing the upper surface of the circuit board 14, and covers the sensor substrates 11, 12, and 13 and the circuit board 14.

The sensor substrate 11 is a substrate including a MEMS section 11A that detects a force in a first direction (an X-axis direction). An X-axis corresponds, for example, to one axis parallel to an arrangement direction of the multiple MEMS three-axis force sensors 10. The sensor substrate 11 includes, for example, a silicon substrate, and the MEMS section 11A includes, for example, MEMS formed on the silicon substrate. The MEMS section 11A detects a component in the first direction (the X-axis direction) of an external force inputted via the organic member 16, and outputs a detection signal based on the detected external force. The MEMS section 11A corresponds to a specific example of a “sensor section” of the present disclosure.

The sensor substrate 12 is a substrate including a MEMS section 12A that detects a force in a second direction (a Y-axis direction). A Y-axis corresponds, for example, to one axis perpendicular to the arrangement direction of the multiple MEMS three-axis force sensors 10. The sensor substrate 12 includes, for example, a silicon substrate, and the MEMS section 12A includes, for example, MEMS formed on the silicon substrate. The MEMS section 12A detects a component in the second direction (the Y-axis direction) of the external force inputted via the organic member 16, and outputs a detection signal based on the detected external force. The MEMS section 12A corresponds to a specific example of the “sensor section” of the present disclosure.

The sensor substrate 13 is a substrate including a MEMS section 13A that detects a force in a third direction (a Z-axis direction). A Z-axis corresponds, for example, to one axis perpendicular to the X-axis and the Y-axis. The sensor substrate 13 includes, for example, a silicon substrate, and the MEMS section 13A includes, for example, MEMS formed on the silicon substrate. The MEMS section 13A detects a component in the third direction (the Z-axis direction) of the external force inputted via the organic member 16, and outputs a detection signal based on the detected external force. The sensor substrates 11, 12, and 13 have respective force detection directions different from each other. The MEMS section 13A corresponds to a specific example of the “sensor section” of the present disclosure.

The circuit board 14 is provided at a position opposing the sensor substrates 11, 12, and 13, and is a support substrate that supports the sensor substrates 11, 12, and 13. The circuit board 14 includes a processing circuit that processes the detection signals outputted from the sensor substrates 11, 12, and 13. For example, the circuit board 14 includes a control circuit 141, a DSP (Digital Signal Processing) circuit 142, and a SerDes (SERializer/DESerializer) circuit 143 as the processing circuits. The control circuit 141 controls external force detection in the MEMS sections 11A, 12A, and 13A. The DSP circuit 142 processes the detection signals obtained from the MEMS sections 11A, 12A, and 13A. Upon receiving a trigger signal, the control circuit 141 supplies, to the MEMS sections 11A, 12A, and 13A, a signal that controls the external force detection in the MEMS sections 11A, 12A, and 13A. Upon receiving the signal that controls the external force detection from the control circuit 141, the MEMS sections 11A, 12A, and 13A each output a detection signal based on the detected external force.

The DSP circuit 142 performs various kinds of signal processing on the detection signals supplied from the MEMS sections 11A, 12A, and 13A. For example, the DSP circuit 142 calculates displacements of the organic member 16 in three axis directions (the X-axis, the Y-axis, and the Z-axis) caused by an external force, on the basis of the detection signals supplied from the MEMS sections 11A, 12A, and 13A, and outputs them to an outside. The SerDes circuit 143 performs serial/parallel conversion on a signal supplied from the DSP circuit 142. The SerDes circuit 143 outputs, to the outside, a signal after the serial/parallel conversion as measured data 10a (packet data). The DSP circuit 142 and the SerDes circuit 143 correspond to a specific example of a “processing circuit” of the present disclosure.

A size of each of the sensor substrates 11, 12, and 13 in an XY plane is, for example, smaller than a size of the circuit board 14 in the XY plane. For example, the sensor substrate 11 is stacked (mounted) on the upper surface of the circuit board 14 with multiple bumps 11B interposed therebetween. For example, the MEMS section 11A in the sensor substrate 11 is electrically coupled to the circuit board 14 (the control circuit 141 and the DSP circuit 142) via the multiple bumps 11B. For example, the sensor substrate 12 is stacked (mounted) on the upper surface of the circuit board 14 with multiple bumps 12B interposed therebetween. For example, the MEMS section 12A in the sensor substrate 12 is electrically coupled to the circuit board 14 (the control circuit 141 and the DSP circuit 142) via the multiple bumps 12B. For example, the sensor substrate 13 is stacked (mounted) on the upper surface of the circuit board 14 with multiple bumps 13B interposed therebetween. For example, the MEMS section 13A in the sensor substrate 13 is electrically coupled to the circuit board 14 (the control circuit 141 and the DSP circuit 142) via the multiple bumps 13B. The bumps 11B, 12B, and 13B each correspond to a specific example of a “bump” of the present disclosure. The bumps 11B, 12B, and 13B include, for example, a solder material.

The wiring substrate 15 includes a wiring line 15A adapted to electrically coupling the coupling line L and the circuit board 14 (the control circuit 141 and the SerDes circuit 143). The wiring substrate 15 is, for example, a flexible substrate including the wiring line 15A and a resin layer that supports the wiring line 15A. Mounted on an upper surface of the wiring substrate 15 are the sensor substrates 11, 12, and 13 and the circuit board 14. For example, the circuit board 14 is stacked on the upper surface of the wiring substrate 15 with multiple bumps 14A interposed therebetween. The bump 14A includes, for example, a solder material. The circuit board 14 is electrically coupled to the wiring substrate 15 (the wiring line 15A) via the multiple bumps 14A. The wiring substrate 15 (the wiring line 15A) is electrically coupled to an external circuit. The multiple bumps 14A are covered, for example, with an underfill 14B.

The organic member 16 is a flexible organic member that has softness that allows for deformation caused by an external force. For example, the organic member 16 includes silicone. The organic member 16 has, for example, a dome shape or a trapezoidal shape. For example, when an external force is applied to the organic member 16, the organic member 16 is deformed, thereby allowing the external force inputted to the organic member 16 to be transmitted to the MEMS sections 11A, 12A, and 13A.

In the present embodiment, the organic member 16 is provided in common to the MEMS three-axis force sensors 10, and fixes the multiple MEMS three-axis force sensors 10 in series. The organic member 16 has grooves 16A each formed at a location corresponding to a gap between two circuit boards 14 adjacent to each other, and has protrusions 16B each formed at a location corresponding to a gap between two grooves 16A adjacent to each other. For example, each of the grooves 16A extends in the Y-axis direction, and partitions the organic member 16 for each MEMS three-axis force sensor 10.

The groove 16A is formed at a position shallower than that of bottom surfaces of the sensor substrates 11, 12, and 13, and is preferably formed at a position shallower than that of upper surfaces of the sensor substrates 11, 12, and 13. That is, the groove 16A is so formed as to satisfy the following Expressions (1) and (2).

D1<D3 Expression (1)

D1<D2 Expression (2)

D1: a depth of the groove 16A
D2: a depth of the upper surfaces of the sensor substrates 11, 12, and 13 from a surface of the organic member 16
D3: a depth of the bottom surfaces of the sensor substrates 11, 12, and 13 from the surface of the organic member 16

The groove 16A suppresses propagation of a force from the outside to the MEMS three-axis force sensor 10 provided at a position away from the input position. The protrusion 16B makes it easier, when a force is inputted to the organic member 16 from the outside, for the force from the outside to be inputted to the MEMS three-axis force sensor 10 corresponding to the input position. In other words, the organic member 16 has both a function of supporting the multiple MEMS three-axis force sensors 10 in series and a function of selectively inputting a force from the outside to the MEMS three-axis force sensor 10 corresponding to the input position.

In each of the MEMS three-axis force sensors 10, the coupling line L and the wiring substrate 15 (specifically, the wiring line 15A) are coupled to each other, and the coupling line L and the circuit board 14 (specifically, the control circuit 141 and the SerDes circuit 143) are electrically coupled to each other. In the MEMS force sensor module 1, a gap G1 between two wiring substrates 15 adjacent to each other is smaller than an arrangement pitch P of the multiple MEMS three-axis force sensors 10. In the MEMS force sensor module 1, a gap G2 between two circuit boards 14 adjacent to each other is smaller than the arrangement pitch P of the multiple MEMS three-axis force sensors 10. The gap G1 is smaller than the gap G2. The arrangement pitch P is, for example, about 1 mm.

For example, as illustrated in FIG. 1, the MEMS force sensor module 1 includes a control device 20 coupled, via the coupling line L, to a MEMS three-axis force sensor 10 (10A) disposed at one end, of the multiple MEMS three-axis force sensors 10 coupled in series. The control device 20 controls external force detection in each of the MEMS three-axis force sensors 10. The control device 20 supplies a trigger signal controlling the external force detection in the MEMS three-axis force sensor 10 to the MEMS three-axis force sensor 10A at a predetermined cycle.

Upon receiving the trigger signal, the MEMS three-axis force sensor 10A supplies the measured data 10a including the detection signal based on the external force inputted from the outside as packet data to a MEMS three-axis force sensor 10 adjacent to the MEMS three-axis force sensor 10A via the coupling line L. Upon receiving the packet data from the MEMS three-axis force sensor 10A via the coupling line L, the MEMS three-axis force sensor 10 adjacent to the MEMS three-axis force sensor 10A regards this input as the trigger signal to detect the external force, and outputs the measured data 10a including the detection signal based on the external force as packet data. The MEMS three-axis force sensor 10 adjacent to the MEMS three-axis force sensor 10A supplies, to a MEMS three-axis force sensor 10 adjacent thereto, packet data including the measured data 10a obtained by the MEMS three-axis force sensor 10A and the measured data 10a obtained by its own measurement, via the coupling line L. In the MEMS force sensor module 1, a control of external force detection and data transmission are thus performed in a bucket relay manner.

For example, as illustrated in FIG. 1, the MEMS force sensor module 1 further includes an interface device 30 coupled, via the coupling line L, to a MEMS three-axis force sensor 10 (10B) disposed at the other end, of the multiple MEMS three-axis force sensors 10A coupled in series. The interface device 30 outputs, to the outside, the detection signals obtained by the sensor substrates 11, 12, and 13 in each of the MEMS three-axis force sensors 10 or a signal corresponding to the detection signals (packet data including the measured data 10a).

For example, as illustrated in FIG. 1, the MEMS force sensor module 1 further includes a power supply circuit 40 that supplies electric power to the multiple MEMS three-axis force sensors 10 coupled in series. The power supply circuit 40 supplies a power supply voltage Vcc from a side of the MEMS three-axis force sensor 10A in the multiple MEMS three-axis force sensors 10 coupled in series.

### [Operation]

Next, operation of the MEMS force sensor module 1 is described.

A trigger signal is supplied from the control device 20 to the control circuit 141 via the wiring substrate 15. Upon receiving the trigger signal, the control circuit 141 supplies, to the MEMS sections 11A, 12A, and 13A, a signal adapted to detecting an external force. Upon receiving the signal adapted to detecting the external force from the control circuit 141, the MEMS sections 11A, 12A, and 13A each supply a detection signal based on the detected external force to the DSP circuit 142. The DSP circuit 142 performs various kinds of signal processing on the received detection signals. For example, the DSP circuit 142 calculates the displacements of the organic member 16 in the three axis directions (the X-axis, the Y-axis, and the Z-axis) caused by the external force, on the basis of the detection signals supplied from the MEMS sections 11A, 12A, and 13A, and outputs them to the SerDes circuit 143. The SerDes circuit 143 performs serial/parallel conversion on a signal supplied from the DSP circuit 142, and outputs packet data as the measured data 10a to the interface device 30. The interface device 30 outputs, to the outside, the detection signals obtained by the sensor substrates 11, 12, and 13 in each of the MEMS three-axis force sensors 10 or a signal corresponding to the detection signals (packet data including the measured data 10a). The MEMS three-axis force sensor 10 executes the above-described process each time the trigger signal is supplied from the control device 20.

### [Effects]

Next, effects of the MEMS force sensor module 1 are described.

In the present embodiment, the multiple MEMS three-axis force sensors 10 are disposed in series by the flexible organic member 16. Accordingly, for example, it is possible to dispose the multiple MEMS three-axis force sensors 10 at a high density independently of a shape of an installation target. In addition, in the present embodiment, the groove 16A is formed in the organic member 16 at a location corresponding to the gap between the two circuit boards 14 adjacent to each other. Accordingly, when a force is inputted to the organic member 16 from the outside, the force from the outside is inputted to the MEMS three-axis force sensor 10 corresponding to the input position, and propagation of the force from the outside to the MEMS three-axis force sensor 10 at a position away from the input position is suppressed. That is, the organic member 16 has both the function of supporting the multiple MEMS three-axis force sensors 10 in series and the function of selectively inputting the force from the outside to the MEMS three-axis force sensor 10 corresponding to the input position. Therefore, in the present embodiment, it is possible to achieve high-density disposing of the multiple MEMS three-axis force sensors 10 and high-resolution detection by the multiple MEMS three-axis force sensors 10.

In the present embodiment, the groove 16A is formed at a position shallower than that of the bottom surfaces of the sensor substrates 11, 12, and 13. Accordingly, it is possible to suppress propagation of the force from the outside to the MEMS three-axis force sensor 10 provided at a position away from the input position. As a result, it is possible to achieve high-resolution detection by the multiple MEMS three-axis force sensors 10.

In the present embodiment, the groove 16A is formed at a position shallower than that of the upper surfaces of the sensor substrates 11, 12, and 13. Accordingly, it is possible to further suppress the propagation of the force from the outside to the MEMS three-axis force sensor 10 provided at a position away from the input position. As a result, it is possible to achieve high-resolution detection by the multiple MEMS three-axis force sensors 10.

In the present embodiment, the circuit board 14 is provided at the position opposing the MEMS sections 11A, 12A, and 13A. Accordingly, as compared with a case where the circuit board 14 is provided in the same surface as the MEMS sections 11A, 12A, and 13A, it is possible to dispose the multiple MEMS three-axis force sensors 10 at a high density.

In the present embodiment, the sensor substrates 11, 12, and 13 are mounted on the circuit board 14 with the bumps 11B, 12B, and 13B interposed therebetween, and the MEMS sections 11A, 12A, and 13A are electrically coupled to the circuit board 14 (the control circuit 141 and the SerDes circuit 143) via the bumps 11B, 12B, and 13B. Accordingly, as compared with the case where the circuit board 14 is provided in the same surface as the MEMS sections 11A, 12A, and 13A, it is possible to dispose the multiple MEMS three-axis force sensors 10 at a high density.

In the present embodiment, in each of the MEMS three-axis force sensors 10, the wiring substrate 15 is provided at the position opposing the circuit board 14. Accordingly, as compared with a case where the wiring substrate 15 is provided in the same surface as the circuit board 14, it is possible to dispose the multiple MEMS three-axis force sensors 10 at a high density.

In the present embodiment, the control device 20 and the interface device 30 are provided. Accordingly, it is possible to perform a control of the external force detection of the multiple MEMS three-axis force sensors 10 coupled in series, transmission of data obtained by the multiple MEMS three-axis force sensors 10 coupled in series, and the like in a bucket relay manner. Therefore, it is possible to achieve the control of the external force detection and the data transmission by a simple method.

In the present embodiment, the gap G2 between the two circuit boards 14 adjacent to each other is smaller than the arrangement pitch P of the multiple MEMS three-axis force sensors 10. Accordingly, it is possible to dispose the multiple MEMS three-axis force sensors 10 at a high density.

In the present embodiment, the gap G1 between the two wiring substrates 15 adjacent to each other is smaller than the arrangement pitch P of the multiple MEMS three-axis force sensors 10. Accordingly, it is possible to dispose the multiple MEMS three-axis force sensors 10 at a high density.

In the present embodiment, the MEMS sections 11A, 12A, and 13A are provided for each of the MEMS three-axis force sensors 10. Accordingly, it is possible to detect inputs of a force in three axis directions (the X-axis, the Y-axis, and the Z-axis). Therefore, for example, it is possible to control the robot hand more precisely.

### 2. Modifications of First Embodiment

Next, modifications of the MEMS force sensor module 1 according to the above-described embodiment are described.

### [Modification 1-1]

In the above-described embodiment, for example, as illustrated in FIG. 5, the MEMS sections 11A, 12A, and 13A may be provided on a common sensor substrate 17. In other words, the sensor substrate 17 includes all of the MEMS sections 11A, 12A, and 13A. The sensor substrate 17 corresponds to a specific example of a “common sensor substrate” of the present disclosure.

In this case, the groove 16A is formed at a position shallower than that of a bottom surface of the sensor substrate 17, and is preferably formed at a position shallower than that of an upper surface of the sensor substrate 17. That is, the groove 16A is so formed as to satisfy the following Expressions (3) and (4). In this case also, effects similar to those of the embodiment described above are obtainable.

D1<D3 Expression (3)

D1<D2 Expression (3)

D1: a depth of the groove 16A
D2: a depth of the upper surface of the sensor substrate 17 from the surface of the organic member 16 D3: a depth of the bottom surface of the sensor substrate 17 from the surface of the organic member 16

### [Modification 1-2]

In the embodiment and the modification thereof described above, for example, as illustrated in FIG. 6, two sensor substrates 11 disposed side by side in the X-axis direction, two sensor substrates 12 disposed side by side in the Y-axis direction, two sensor substrates 13 disposed side by side in a direction intersecting the X-axis at 45° in the XY plane, and two sensor substrates 13 disposed side by side in a direction intersecting the X-axis at −45° in the XY plane may be provided for each of the MEMS three-axis force sensors 10.

In such a case, a moment component in a rotational direction around the Y-axis as a central axis is obtainable from detection signals obtained by the two sensor substrates 11 disposed side by side in the X-axis direction. In addition, a moment component in a rotational direction around the X-axis as a central axis is obtainable from detection signals obtained by the two sensor substrates 12 disposed side by side in the Y-axis direction. In addition, a moment component in a rotational direction around the Z-axis as a central axis is obtainable from detection signals obtained by the two sensor substrates 13 disposed side by side in the direction intersecting the X-axis at 45° in the XY plane and the two sensor substrates 13 disposed side by side in the direction intersecting the X-axis at −45° in the XY plane. That is, in the present modification, the MEMS force sensor module 1 is able to detect force components of six axes.

### [Modification 1-3]

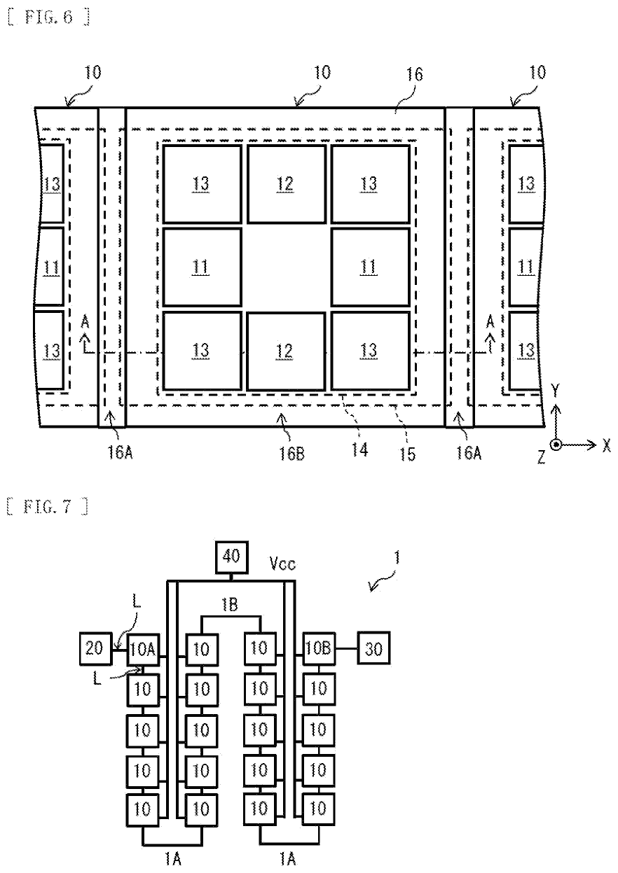

In the embodiment and the modifications thereof described above, in a case where the MEMS force sensor module 1 includes a large number of MEMS three-axis force sensors 10, for example, as illustrated in FIG. 7, it is preferable that the multiple MEMS three-axis force sensors 10 coupled in series have a zigzag serpentine layout. In such a case, it is possible for the power supply circuit 40 to supply the power supply voltage Vcc from a side of a U-turn portion 1A of the multiple MEMS three-axis force sensors 10 coupled in series, and supply a reference voltage GND to a side of a U-turn portion 1B corresponding to the U-turn portion 1A in the multiple MEMS three-axis force sensors 10 coupled in series. This prevents a malfunction of a sensor due to a voltage drop.

### 3. Second Embodiment

### [Configuration]

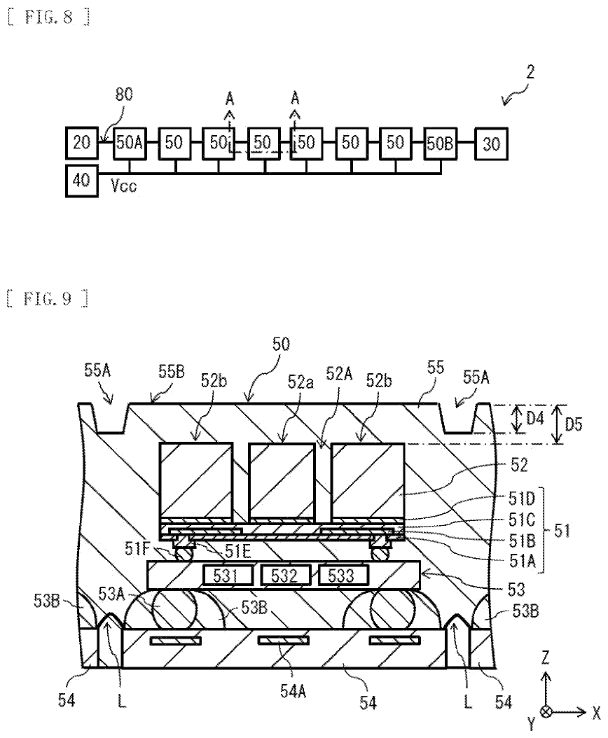

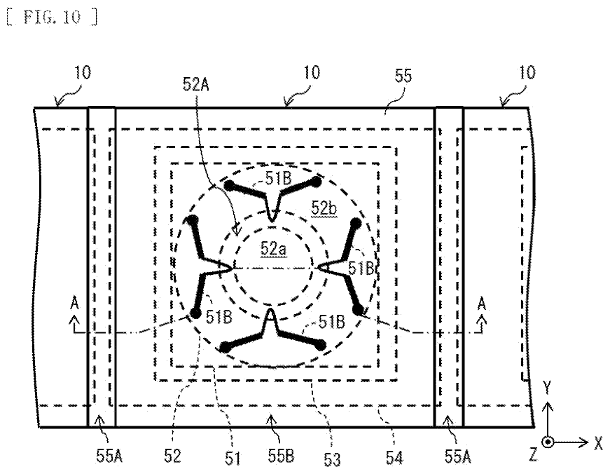

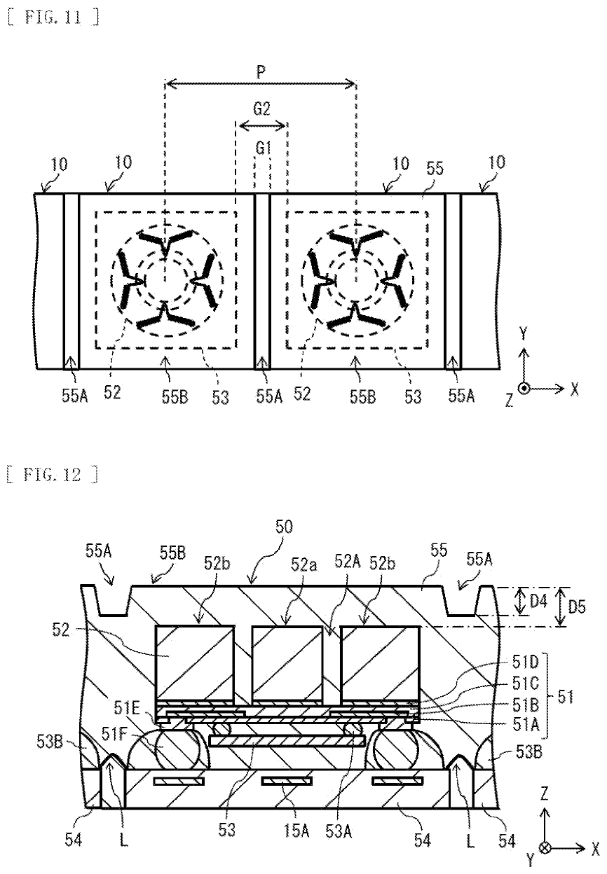

A description is given of a configuration of a diaphragm force sensor module 2 according to a second embodiment of the present disclosure. FIG. 8 illustrates an example of a plan configuration of the diaphragm force sensor module 2 according to the present embodiment. FIG. 9 illustrates an example of a cross-sectional configuration of the diaphragm force sensor module 2 in FIG. 8 taken along a line A-A. FIGS. 10 and 11 each illustrate a portion of the example of the plan configuration of the diaphragm force sensor module 2 in FIG. 9 in an enlarged manner.

The diaphragm force sensor module 2 includes multiple diaphragm six-axis force sensors 50 coupled in series via the coupling line L. For example, the coupling line L basically includes a clock pair differential line and a data pair differential line, and also includes several kinds of other control lines. The diaphragm force sensor module 2 corresponds to a specific example of the “force sensor module” of the present disclosure. The diaphragm six-axis force sensor 50 corresponds to a specific example of the “force sensor” of the present disclosure. The coupling line L corresponds to a specific example of the “coupling line” of the present disclosure.

The diaphragm six-axis force sensor 50 includes a sensor substrate 51, a force transfer section 52, a circuit board 53, a wiring substrate 54, and an organic member 55. The sensor substrate 51 corresponds to a specific example of a “common sensor substrate” of the present disclosure. The circuit board 53 corresponds to a specific example of the “support substrate” of the present disclosure. The wiring substrate 54 corresponds to a specific example of the “wiring substrate” of the present disclosure. The organic member 55 corresponds to a specific example of the “organic member” of the present disclosure.

The sensor substrate 51 and the circuit board 53 are stacked on each other. The sensor substrate 51 is disposed at a position opposing an upper surface of the circuit board 53. The sensor substrate 51 and the force transfer section 52 are stacked on each other. The force transfer section 52 is disposed at a position opposing an upper surface of the sensor substrate 51. The wiring substrate 54 is disposed at a position opposing a lower surface of the circuit board 53. The organic member 55 is disposed at a position opposing the upper surface of the circuit board 53, and covers the sensor substrate 51, the force transfer section 52, and the circuit board 53.

The sensor substrate 51 is included in a diaphragm that is able to detect forces of six axes. For example, the sensor substrate 51 includes an insulating film 51A, four electrically conductive layers 51B, a flexible substrate 51C, and an insulating film 51D that are stacked in this order from a side of the circuit board 53. The four electrically conductive layers 51B each correspond to a specific example of the “sensor section” of the present disclosure. The flexible substrate 51C corresponds to a specific example of a “flexible substrate” of the present disclosure. The insulating films 51A and 51D cover the four electrically conductive layers 51B. For example, the insulating films 51A and 51D include SiO₂ or the like.

The four electrically conductive layers 51B are provided in contact with a bottom surface of the flexible substrate 51C, and are supported by the flexible substrate 51C. In a case where the flexible substrate 51C includes a thin-film silicon substrate, the four electrically conductive layers 51B are formed, for example, by doping the thin-film silicon substrate with an impurity at a high concentration. For example, the four electrically conductive layers 51B are disposed circularly around a middle of the sensor substrate 51. For example, a portion of each of the electrically conductive layers 51B is provided at a position opposing a groove 52A which will be described later. Two electrically conductive layers 51B of the four electrically conductive layers 51B extend, for example, in the X-axis direction, and the remaining two electrically conductive layers 51B of the four electrically conductive layers 51B extend, for example, in the Y-axis direction.

The sensor substrate 11 further includes, for example, eight pad electrodes 51E and eight bumps 51F. The eight pad electrodes 51E are provided for each electrically conductive layer 51B on a two-to-one basis. The eight bumps 51F are provided for each pad electrode 51E on a one-to-one basis. The pad electrode 51E includes, for example, a metal material such as gold (Au). The bump 51F includes, for example, a solder material.

The force transfer section 52 includes, for example, a column part 52a and a tube part 52b. The column part 52a is fixed at a position opposing the middle of the sensor substrate 51 (a center of the four electrically conductive layers 51B disposed circularly). The tube part 52b is fixed, on the sensor substrate 51, at a position that is around the column part 52a and has a predetermined gap from the column part 52a. The column part 52a corresponds to a specific example of a “column part” of the present disclosure. The tube part 52b corresponds to a specific example of a “tube part” of the present disclosure. The gap between the column part 52a and the tube part 52b forms the groove 52A. The sensor substrate 51 is exposed at a bottom surface of the groove 52A. A portion of each of the electrically conductive layers 51B included in the sensor substrate 51 is disposed at a position opposing the bottom surface of the groove 52A. The column part 52a and the tube part 52b are formed, for example, by processing a silicon substrate.

The circuit board 53 is provided at a position opposing the sensor substrate 51, and is a support substrate that supports the sensor substrate 51. The circuit board 53 includes a processing circuit that processes a detection signal outputted from the sensor substrate 51. For example, the circuit board 53 includes a control circuit 531, a DSP circuit 532, and a SerDes circuit 533 as the processing circuits. The control circuit 531 controls external force detection in the four electrically conductive layers 51B. The DSP circuit 532 processes detection signals obtained from the four electrically conductive layers 51B. Upon receiving a trigger signal, the control circuit 531 supplies, to the four electrically conductive layers 51B, a signal that controls the external force detection in the four electrically conductive layers 51B. Upon receiving the signal that controls the external force detection from the control circuit 531, the four electrically conductive layers 51B each output a detection signal based on the detected external force.

The DSP circuit 532 performs various kinds of signal processing on the detection signals supplied from the four electrically conductive layers 51B. For example, the DSP circuit 532 calculates displacements of the organic member 55 in six axis directions caused by an external force, on the basis of the detection signals supplied from the four electrically conductive layers 51B, and outputs them to the outside. The SerDes circuit 533 performs serial/parallel conversion on a signal supplied from the DSP circuit 532. The SerDes circuit 533 outputs, to the outside, a signal after the serial/parallel conversion as the measured data 10a (packet data). The DSP circuit 532 and the SerDes circuit 533 correspond to a specific example of the “processing circuit” of the present disclosure.

A size of the sensor substrate 51 in the XY plane is, for example, smaller than a size of the circuit board 53 in the XY plane. For example, the sensor substrate 51 is stacked on the upper surface of the circuit board 53 with the multiple bumps 51F interposed therebetween. The sensor substrate 51 (the four electrically conductive layers 51B) is electrically coupled to the circuit board 53 (the control circuit 531 and the DSP circuit 532) via the multiple bumps 51F.

The wiring substrate 54 includes a wiring line 54A adapted to electrically coupling an external circuit and the circuit board 53 (the control circuit 531 and the SerDes circuit 533). The wiring substrate 54 is, for example, a flexible substrate including the wiring line 54A and a resin layer that supports the wiring line 54A. Mounted on an upper surface of the wiring substrate 54 are the sensor substrate 51, the force transfer section 52, and the circuit board 53. For example, the circuit board 53 is stacked on the upper surface of the wiring substrate 54 with multiple bumps 53A interposed therebetween. The bump 53A includes, for example, a solder material. The circuit board 53 is electrically coupled to the wiring substrate 54 (the wiring line 54A) via the multiple bumps 53A. The multiple bumps 53A are covered, for example, with an underfill 53B.

The organic member 55 is a flexible organic member that has softness that allows for deformation caused by an external force. For example, the organic member 55 includes silicone. The organic member 55 has, for example, a dome shape or a trapezoidal shape. For example, when an external force is applied to the organic member 55, the organic member 55 is deformed, thereby allowing the external force inputted to the organic member 55 to be transmitted to the four electrically conductive layers 51B.

In the present embodiment, the organic member 55 is provided in common to the diaphragm six-axis force sensors 50, and fixes the multiple diaphragm six-axis force sensors 50 in series. The organic member 55 has grooves 55A each formed at a location corresponding to a gap between two circuit boards 53 adjacent to each other, and has protrusions 55B each formed at a location corresponding to a gap between two grooves 55A adjacent to each other. For example, each of the grooves 55A extends in the Y-axis direction, and partitions the organic member 55 for each diaphragm six-axis force sensor 50.

The groove 55A is formed at a position shallower than that of the upper surface of the sensor substrate 51. That is, the groove 55A is so formed as to satisfy the following Expression (3).

D4<D5 Expression (3)

D4: a depth of the groove 55A

D5: a depth of the upper surface of the sensor substrate 51 from a surface of the organic member 55

The groove 55A suppresses propagation of a force from the outside to the diaphragm six-axis force sensor 50 provided at a position away from the input position. The protrusion 55B makes it easier, when a force is inputted to the organic member 55 from the outside, for the force from the outside to be inputted to the diaphragm six-axis force sensor 50 corresponding to the input position. In other words, the organic member 55 has both a function of supporting the multiple diaphragm six-axis force sensors 50 in series and a function of selectively inputting a force from the outside to the diaphragm six-axis force sensor 50 corresponding to the input position.

In each of the diaphragm six-axis force sensors 50, the coupling line L and the wiring substrate 54 (specifically, the wiring line 54A) are coupled to each other, and the coupling line L and the circuit board 53 (specifically, the control circuit 531 and the SerDes circuit 533) are electrically coupled to each other. In the diaphragm force sensor module 2, a gap G1 between two wiring substrates 54 adjacent to each other is smaller than an arrangement pitch P of the multiple diaphragm six-axis force sensors 50. In the diaphragm force sensor module 2, a gap G2 between two circuit boards 53 adjacent to each other is smaller than the arrangement pitch P of the multiple diaphragm six-axis force sensors 50. The gap G1 is smaller than the gap G2. The arrangement pitch P is, for example, about 1 mm.

For example, as illustrated in FIG. 8, the diaphragm force sensor module 2 includes the control device 20 coupled, via the coupling line L, to a diaphragm six-axis force sensor 50 (50A) disposed at one end, of the multiple diaphragm six-axis force sensors 50 coupled in series. The control device 20 controls external force detection in each of the diaphragm six-axis force sensors 50. The control device 20 supplies a trigger signal controlling the external force detection in the diaphragm six-axis force sensor 50 to the diaphragm six-axis force sensor 50A at a predetermined cycle.

Upon receiving the trigger signal, the diaphragm six-axis force sensor 50 supplies the measured data 10a including the detection signal based on the external force inputted from the outside as packet data to a diaphragm six-axis force sensor 50 adjacent to the diaphragm six-axis force sensor 50A via the coupling line L. Upon receiving the packet data from the diaphragm six-axis force sensor 50A via the coupling line L, the diaphragm six-axis force sensor 50 adjacent to the diaphragm six-axis force sensor 50A regards this input as the trigger signal to detect the external force, and outputs the measured data 10a including the detection signal based on the external force as packet data. The diaphragm six-axis force sensor 50 adjacent to the diaphragm six-axis force sensor 50A supplies, to a diaphragm six-axis force sensor 50 adjacent thereto, packet data including the measured data 10a obtained by the diaphragm six-axis force sensor 50A and the measured data 10a obtained by its own measurement, via the coupling line L. In the diaphragm force sensor module 2, a control of external force detection and data transmission are thus performed in a bucket relay manner.

For example, as illustrated in FIG. 8, the diaphragm force sensor module 2 further includes the interface device 30 coupled, via the coupling line L, to a diaphragm six-axis force sensor 50 (50B) disposed at the other end, of the multiple diaphragm six-axis force sensors 50A coupled in series. The interface device 30 outputs, to the outside, the detection signals obtained by the four electrically conductive layers 51B in each of the diaphragm six-axis force sensors 50 or a signal corresponding to the detection signals (packet data including the measured data 10a).

For example, as illustrated in FIG. 8, the diaphragm force sensor module 2 further includes the power supply circuit 40 that supplies electric power to the multiple diaphragm six-axis force sensors 50 coupled in series. The power supply circuit 40 supplies the power supply voltage Vcc from a side of the diaphragm six-axis force sensor 50A in the multiple diaphragm six-axis force sensors 50 coupled in series.

### Operation

Next, operation of the diaphragm force sensor module 2 is described.

A trigger signal is supplied from the control device 20 to the control circuit 531 via the wiring substrate 54. Upon receiving the trigger signal, the control circuit 531 supplies, to the four electrically conductive layers 51B, a signal adapted to detecting an external force. Upon receiving the signal adapted to detecting the external force from the control circuit 531, the four electrically conductive layers 51B each supply a detection signal based on the detected external force to the DSP circuit 532. The DSP circuit 532 performs various kinds of signal processing on the received detection signal. For example, the DSP circuit 532 calculates the displacements of the organic member 16 in the six axis directions caused by the external force, on the basis of the detection signals supplied from the four electrically conductive layers 51B, and outputs them to the SerDes circuit 533. The SerDes circuit 533 performs serial/parallel conversion on a signal supplied from the DSP circuit 532, and outputs packet data as the measured data 10a to the interface device 30. The interface device 30 outputs, to the outside, the detection signals obtained by the four electrically conductive layers 51B in each of the diaphragm six-axis force sensors 50 or a signal corresponding to the detection signals (packet data including the measured data 10a). The diaphragm six-axis force sensor 50 executes the above-described process each time the trigger signal is supplied from the control device 20.

### [Effects]

Next, effects of the diaphragm force sensor module 2 are described.

In the present embodiment, the multiple diaphragm six-axis force sensors 50 are disposed in series by the flexible organic member 55. Accordingly, for example, it is possible to dispose the multiple diaphragm six-axis force sensors 50 at a high density independently of a shape of an installation target. In addition, in the present embodiment, the groove 55A is formed in the organic member 55 at a location corresponding to the gap between the two circuit boards 53 adjacent to each other. Accordingly, when a force is inputted to the organic member 55 from the outside, the force from the outside is inputted to the diaphragm six-axis force sensor 50 corresponding to the input position, and propagation of the force from the outside to the diaphragm six-axis force sensor 50 at a position away from the input position is suppressed. That is, the organic member 55 has both the function of supporting the multiple diaphragm six-axis force sensors 50 in series and the function of selectively inputting the force from the outside to the diaphragm six-axis force sensor 50 corresponding to the input position. Therefore, in the present embodiment, it is possible to achieve high-density disposing of the multiple diaphragm six-axis force sensors 50 and high-resolution detection by the multiple diaphragm six-axis force sensors 50.

In the present embodiment, the groove 55A is formed at a position shallower than that of the upper surface of the sensor substrate 51. Accordingly, it is possible to suppress propagation of the force from the outside to the diaphragm six-axis force sensor 50 at a position away from the input position. As a result, it is possible to achieve high-resolution detection by the multiple diaphragm six-axis force sensors 50.

In the present embodiment, the circuit board 53 is provided at the position opposing the four electrically conductive layers 51B. Accordingly, as compared with a case where the circuit board 53 is provided in the same surface as the four electrically conductive layers 51B, it is possible to dispose the multiple diaphragm six-axis force sensors 50 at a high density.

In the present embodiment, the sensor substrate 51 is mounted on the circuit board 53 with the bumps 51F interposed therebetween, and the four electrically conductive layers 51B are electrically coupled to the circuit board 53 (the control circuit 531 and the SerDes circuit 533) via the bumps 51F. Accordingly, as compared with the case where the circuit board 53 is provided in the same surface as the four electrically conductive layers 51B, it is possible to dispose the multiple diaphragm six-axis force sensors 50 at a high density.

In the present embodiment, in each of the diaphragm six-axis force sensors 50, the wiring substrate 54 is provided at the position opposing the circuit board 53. Accordingly, as compared with a case where the wiring substrate 54 is provided in the same surface as the circuit board 53, it is possible to dispose the multiple diaphragm six-axis force sensors 50 at a high density.

In the present embodiment, the control device 20 and the interface device 30 are provided. Accordingly, it is possible to perform a control of the external force detection of the multiple diaphragm six-axis force sensors 50 coupled in series, transmission of data obtained by the multiple diaphragm six-axis force sensors 50 coupled in series, and the like in a bucket relay manner. Therefore, it is possible to achieve the control of the external force detection and the data transmission by a simple method.

In the present embodiment, the gap G2 between the two circuit boards 53 adjacent to each other is smaller than the arrangement pitch P of the multiple diaphragm six-axis force sensors 50. Accordingly, it is possible to dispose the multiple diaphragm six-axis force sensors 50 at a high density.

In the present embodiment, the gap G1 between the two wiring substrates 54 adjacent to each other is smaller than the arrangement pitch P of the multiple diaphragm six-axis force sensors 50. Accordingly, it is possible to dispose the diaphragm six-axis force sensors 50 at a high density.

In the present embodiment, the four electrically conductive layers 51B are provided for each of the diaphragm six-axis force sensors 50. Accordingly, it is possible to detect inputs of a force in six axis directions. Therefore, for example, it is possible to control the robot hand more precisely.

### 4. Modifications of Second Embodiment

Next, modifications of the diaphragm force sensor module 2 according to the above-described second embodiment are described.

### [Modification 2-1]

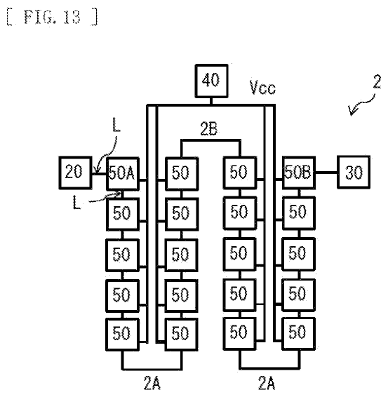

In the above-described second embodiment, for example, as illustrated in FIG. 12, the circuit board 53 may be mounted on a bottom surface of the sensor substrate 51. In this case, the sensor substrate 51 is electrically coupled to the wiring substrate 54 via the bumps 51F. In addition, the circuit board 53 is electrically coupled to the wiring substrate 54 via the bumps 53A, the sensor substrate 51, and the bumps 51F. In this case also, effects similar to those of the second embodiment described above are obtainable.

### [Modification 2-1]

In the second embodiment and the modification thereof described above, in a case where the diaphragm force sensor module 2 includes a large number of diaphragm six-axis force sensors 50, for example, as illustrated in FIG. 13, it is preferable that the multiple diaphragm six-axis force sensors 50 coupled in series have a zigzag serpentine layout. In such a case, it is possible for the power supply circuit 40 to supply the power supply voltage Vcc from a side of a U-turn portion 2A of the multiple diaphragm six-axis force sensors 50 coupled in series, and supply the reference voltage GND to a side of a U-turn portion 2B corresponding to the U-turn portion 2A in the multiple diaphragm six-axis force sensors 50 coupled in series. This prevents a malfunction of a sensor due to a voltage drop.

The present disclosure has been described above with reference to the embodiments and the modifications thereof; however, the present disclosure is not limited to the embodiments and the like described above and may be variously modified. Note that the effects described herein are merely illustrative. Effects of the present disclosure are not limited to the effects described herein. The present disclosure may have effects other than the effects described herein.

Moreover, for example, the present disclosure may have the following configurations.

(1)

A force sensor module including

multiple force sensors disposed in series,

the force sensors each including
multiple sensor sections having respective force detection directions different from each other,
a support substrate separately provided for each of the force sensors and supporting the multiple sensor sections, and
an organic member provided in common to the force sensors, the organic member fixing the multiple force sensors in series and having a groove at a location corresponding to a gap between two the support substrates adjacent to each other, the organic member being flexible.
   (2)

The force sensor module according to (1), in which

each of the force sensors includes multiple sensor substrates or a common sensor substrate, the multiple sensor substrates being provided for the respective sensor sections on a one-to-one basis and including the respective sensor sections, the common sensor substrate including all of the multiple sensor sections, and

the groove is formed at a position shallower than that of bottom surfaces of the multiple sensor substrates or a bottom surface of the common sensor substrate.

(3)

The force sensor module according to (2), in which the groove is formed at a position shallower than that of upper surfaces of the multiple sensor substrates or an upper surface of the common sensor substrate.

(4)

The force sensor module according to (2) or (3), in which the support substrate includes a processing circuit that is provided at a position opposing the multiple sensor sections and processes a detection signal outputted from the multiple sensor sections.

(5)

The force sensor module according to (4), in which

the multiple sensor substrates or the common sensor substrate is mounted on the support substate with a bump interposed therebetween, and

the multiple sensor sections are electrically coupled to the processing circuit via the bump.

(6)

The force sensor module according to (5), further including

a coupling line coupling the multiple force sensors in series, in which

each of the force sensors further includes a wiring substrate provided at a position opposing the support substrate and including a wiring line adapted to electrically coupling the coupling line and the processing circuit.

(7)

The force sensor module according to (6), further including:

a control device coupled, via the coupling line, to a first force sensor disposed at one end of the multiple force sensors coupled in series, the control device controlling the multiple sensor sections in each of the force sensors; and

an interface device coupled, via the coupling line, to a second force sensor disposed at another end of the multiple force sensors coupled in series, the interface device outputting, to an outside, a detection signal obtained by the multiple sensor sections in each of the force sensors or a signal corresponding to the detection signal.

(8)

The force sensor module according to any one of (1) to (7), in which the gap between the two support substrates adjacent to each other is smaller than an arrangement pitch of the multiple force sensors.

(9)

The force sensor module according to any one of (1) to (8), in which the gap between the two wiring substrates adjacent to each other is smaller than an arrangement pitch of the multiple force sensors.

(10)

The force sensor module according to any one of (1) to (9), in which the sensor section includes MEMS (Micro Electro Mechanical Systems).

(11)

The force sensor module according to any one of (1) to (9), in which in each of the force sensors, the multiple sensor sections are disposed circularly, and

each of the force sensors is a diaphragm force sensor that includes
a flexible substrate including the multiple sensor sections,
a column part fixed, on the flexible substrate, at a position opposing a center of the multiple sensor sections disposed circularly, and
a tube part fixed, on the flexible substrate, at a position that is around the column part and has a predetermined gap from the column part.

According to the force sensor module of the embodiment of the present disclosure, the multiple force sensors are disposed in series by the flexible organic member, and the groove is formed, in the organic member, at a location corresponding to the gap between the two support substrates adjacent to each other. Accordingly, it is possible to dispose the multiple force sensors at a high density and with a high resolution. Note that the effects of the present disclosure are not necessarily limited to the effects described above and may be any of the effects described herein.

This application claims the priority on the basis of Japanese Patent Application No. 2019-220840 filed on Dec. 6, 2019 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A force sensor module comprising
multiple force sensors disposed in series,
the force sensors each including
multiple sensor sections having respective force detection directions different from each other,
a support substrate separately provided for each of the force sensors and supporting the multiple sensor sections, and
an organic member provided in common to the force sensors, the organic member fixing the multiple force sensors in series and having a groove at a location corresponding to a gap between two the support substrates adjacent to each other, the organic member being flexible.

2. The force sensor module according to claim 1, wherein
each of the force sensors includes multiple sensor substrates or a common sensor substrate, the multiple sensor substrates being provided for the respective sensor sections on a one-to-one basis and including the respective sensor sections, the common sensor substrate including all of the multiple sensor sections, and
the groove is formed at a position shallower than that of bottom surfaces of the multiple sensor substrates or a bottom surface of the common sensor substrate.

3. The force sensor module according to claim 2, wherein the groove is formed at a position shallower than that of upper surfaces of the multiple sensor substrates or an upper surface of the common sensor substrate.

4. The force sensor module according to claim 2, wherein the support substrate includes a processing circuit that is provided at a position opposing the multiple sensor sections and processes a detection signal outputted from the multiple sensor sections.

5. The force sensor module according to claim 4, wherein
the multiple sensor substrates or the common sensor substrate is mounted on the support substate with a bump interposed therebetween, and
the multiple sensor sections are electrically coupled to the processing circuit via the bump.

6. The force sensor module according to claim 5, further comprising
a coupling line coupling the multiple force sensors in series, wherein
each of the force sensors further includes a wiring substrate provided at a position opposing the support substrate and including a wiring line adapted to electrically coupling the coupling line and the processing circuit.

7. The force sensor module according to claim 6, further comprising:
a control device coupled, via the coupling line, to a first force sensor disposed at one end of the multiple force sensors coupled in series, the control device controlling the multiple sensor sections in each of the force sensors; and
an interface device coupled, via the coupling line, to a second force sensor disposed at another end of the multiple force sensors coupled in series, the interface device outputting, to an outside, a detection signal obtained by the multiple sensor sections in each of the force sensors or a signal corresponding to the detection signal.

8. The force sensor module according to claim 1, wherein the gap between the two support substrates adjacent to each other is smaller than an arrangement pitch of the multiple force sensors.

9. The force sensor module according to claim 1, wherein the gap between the two wiring substrates adjacent to each other is smaller than an arrangement pitch of the multiple force sensors.

10. The force sensor module according to claim 1, wherein the sensor section includes MEMS (Micro Electro Mechanical Systems).

11. The force sensor module according to claim 1, wherein
in each of the force sensors, the multiple sensor sections are disposed circularly, and
each of the force sensors is a diaphragm force sensor that includes
a flexible substrate including the multiple sensor sections,
a column part fixed, on the flexible substrate, at a position opposing a center of the multiple sensor sections disposed circularly, and
a tube part fixed, on the flexible substrate, at a position that is around the column part and has a predetermined gap from the column part.
